(19) United States
(12) Patent Application Publication
(10) Pub. No.: US 2011/0042719 A1
(43) Pub. Date: Feb. 24, 2011

(54) SEMICONDUCTOR DEVICE AND METHOD OF MANUFACTURING A SEMICONDUCTOR DEVICE

(75) Inventors: Hiroyuki Sazawa, Tsukuba-shi (JP); Naohiro Nishikawa, Ichihara-shi (JP); Yasuyukl Kurita, Toride-shi (JP); Masahiko Hata, Tsuchiura-shi (JP)

Correspondence Address: SUGHRUE MION, PLLC, 2100 PENNSYLVANIA AVENUE, N.W., SUITE 800, WASHINGTON, DC, 20037, US

(73) Assignee: SUMITOMO CHEMICAL COMPANY, LIMITED, Chuo-ku, Tokyo (JP)

(21) Appl. No.: 12/933,340

(22) PCT Filed: Mar. 18, 2009
(86) PCT No.: PCT/JP2009/001209

§ 371 Date: Nov. 5, 2010

(30) Foreign Application Priority Data
Mar. 19, 2008 (JP) 2008-072583

(51) Int. Cl. H01L 29/78; H01L 21/336

(52) U.S. Cl. 257/190; 438/285; 257/E29.255; 257/E21.411

(57) ABSTRACT

It is an objective of the present invention to increase channel current density while allowing a GaN field effect transistor to perform normally-off operation.

Provided is a a semiconductor device comprising a group 3-5 compound semiconductor channel layer including nitrogen; an electron supply layer that has a groove in a surface thereof that is opposite a surface facing the channel layer and that supplies the channel layer with electrons; a p-type semiconductor layer that is formed in the groove of the electron supply layer; and a control electrode formed directly on the p-type semiconductor layer or on an intermediate layer formed on the p-type semiconductor layer.

### TECHNICAL FIELD

The present invention relates to a semiconductor device and a method of manufacturing a semiconductor device. In particular, the present invention relates to semiconductor devices such as heterojunction field effect transistors using a group 3-5 compound semiconductor containing nitrogen, such as gallium nitride, and to a method of manufacturing these semiconductor devices.

### BACKGROUND ART

Gallium nitride-based heterojunction field effect transistors can operate at high frequency and are expected to be used as switching devices that are capable of being used at high power. For example, a device having a channel that is a two-dimensional gas (2DEG) generated at an interface between n-type AlGaN and intrinsic GaN can be implemented as an AlGaN/GaN-HEMT (High Electron Mobility Transistor). Such an AlGaN/GaN-HEMT is desirably a normally-off type whose source/drain junction has high impedance even when voltage is not applied to the gate, i.e. the HEMT is desirably able to operate in an enhancement mode. As a result, the transistor can operate using a single polarity power supply and can have low power consumption.

A known method for achieving transistor operation in the enhancement mode involves, for example, using a structure having a recess (groove) that is a portion of the electron supply layer (an AlGaN layer in the case of an AlGaN/GaN-HEMT) in a gate region formed to be thinner than other regions. For example, Non-Patent Document 1 discloses a normally-off AlGaN/GaN transistor that has a gate recess formed by dry etching in the AlGaN layer thereof.

Non-Patent Document 1: R. Wang et al., “Enhancement-Mode Si3N4/AlGaN/GaN MISHFETs,” IEEE Electron Device Letters, Vol. 27, No. 10, October 2006, pp. 793-795.

By forming the groove in a portion of the AlGaN layer, the electron density of the 2DEG region facing the groove region is decreased, which enables depletion of a portion of the 2DEG at an interface between the AlGaN layer and the GaN layer. As a result, the channel can be in a disconnected state even when a gate voltage is not being applied. Therefore, a normally-off mode can be achieved in which the source/drain junction of the transistor has high impedance. When a voltage is applied to the gate electrode so that electrons are induced in the 2DEG region facing the groove region, the channel conducts, thereby achieving operation in the enhancement mode.

### DISCLOSURE OF THE INVENTION

### Problems to be Solved by the Invention

In the transistor of Non-Patent Document 1, however, the inventor of the present invention has noticed a problem that the current density of the channel current cannot be made sufficiently large. In other words, while forming a thin groove in the electron supply layer (AlGaN layer) enables implementation of the enhancement mode, it also causes an intermediate level due to crystal imperfections at the bottom surface of the groove. When electrons are charged at this intermediate level due to a voltage applied to the gate electrode, the charged electrons repulse the electrons that form the 2DEG, and so the channel resistance increases and the current density of the channel decreases. When used as a switching device, operation at relatively high voltage thresholds of +1 V to +3 V is required. Therefore, due to the decrease in the channel current density, even if the threshold is +2 V, an element resistance that is sufficiently low for actual application cannot be achieved.

The current density decrease caused by the space charge at the bottom of the groove can be somewhat mitigated by distancing the groove from the 2DEG region, i.e. by forming the groove to be shallow. However, making the groove shallow shifts the gate threshold value in a negative direction, and this prevents realization of the normally-off operation. In other words, there is a tradeoff between increasing the channel current density and achieving the normally-off operation, i.e. increasing the gate threshold value, and so there is a limit to how much a switching device can be improved.

Furthermore, in the transistor of Non-Patent Document 1, an insulating film is formed in order to decrease the gate leak within the groove of the channel region. Therefore, a depletion section that is difficult to control with the gate voltage remains at the source end and the drain end on the bottom surface of the groove, and this depletion section operates as a parasitic resistance during conduction, which decreases the channel current density.

### Means for Solving the Problems

According to a first embodiment of the present invention, provided is a semiconductor device comprising a group 3-5 compound semiconductor channel layer; a carrier supply layer that has a groove in a surface thereof that is opposite a surface facing the channel layer and that supplies the channel layer with carriers; a semiconductor layer that is formed in the groove of the carrier supply layer and that has a conduction type opposite that of the carriers; and a control electrode disposed on the semiconductor layer. Another example according to a first embodiment of the present invention is a semiconductor device comprising a group 3-5 compound semiconductor channel layer including nitrogen; an electron supply layer that has a groove in a surface thereof that is opposite a surface facing the channel layer and that supplies the channel layer with electrons; a p-type semiconductor layer that is formed in the groove of the electron supply layer; and a control electrode formed directly on the p-type semiconductor layer or on an intermediate layer formed on the p-type semiconductor layer.

In the first embodiment, the semiconductor layer may be a group 3-5 compound semiconductor layer including nitrogen. The semiconductor layer may be an InGaN layer, an AlGaN layer, or a GaN layer. The semiconductor layer may be an AlₓGa₁₋ₓN layer, where 0≦x≦0.5. An insulating layer may be formed between the control electrode and the semiconductor layer. The insulating layer may be a layer including at least one insulating compound selected from a group consisting of SiOₓ, SiNₓ, SiAlₓO_{y}N_{z}, HfOₓ, HfAlₓO_{y}, HfSiₓO_{y}, HfNₓO_{y}, AlOₓ, AlNₓO_{y}, GaOₓ, GaOₓN_{y}, TaOₓ, and TiNₓO_{y}. Here, the chemical formulas including x, y, and z represent insulating compounds, as described above, and represent compounds whose elemental composition ratios are expressed as stoichiometric ratios or compounds whose elemental composition ratios are not expressed as stoichiometric ratios due to the inclusion of defects or amorphous structures.

In the first embodiment, the semiconductor device may further comprise a passivation layer that covers the carrier supply layer and that includes an open portion matching an opening of the groove. The carrier supply layer may lattice match or pseudo-lattice match with the channel layer, and the semiconductor layer may lattice match or pseudo-lattice match with the carrier supply layer. The channel layer may include nitrogen. The channel layer may be a GaN layer, an InGaN layer, or an AlGaN layer, and the carrier supply layer may be an AlGaN layer, an AlInN layer, or an AlN layer. The control electrode may include at least one metal selected from a group consisting of Ni, Al, Mg, Sc, Ti, Mn, Ag, Sn, Pt, and In. The carriers may be electrons.

According to a second embodiment of the present invention, provided is a method of manufacturing a semiconductor device, comprising forming a groove in a top surface of a carrier supply layer that supplies a group 3-5 compound semiconductor channel layer with carriers; forming, in the groove of the carrier supply layer, a semiconductor layer that has a conduction type opposite that of the carriers; and after forming the semiconductor layer, forming a control electrode. Another example according to a second embodiment of the present invention is a method of manufacturing a semiconductor device, preparing a wafer having a group 3-5 compound semiconductor channel layer including nitrogen and an electron supply layer that supplies electrons to the channel layer and that forms a top surface of the wafer; forming a groove in a top surface of the electron supply layer; forming a p-type semiconductor layer in the groove of the electron supply layer; and after forming the p-type semiconductor layer, forming a control electrode.

In the second embodiment, the method of manufacturing a semiconductor device may further comprise forming a passivation layer that covers the carrier supply layer; and forming an open portion in the passivation layer in a region where the groove is formed. Forming the groove in the top surface of the carrier supply layer may include forming the groove by etching the carrier supply layer that is exposed by the open portion of the passivation layer. Forming the semiconductor layer may include selectively growing an epitaxial layer that becomes the semiconductor layer on the carrier supply layer exposed by the open portion of the passivation layer. Forming the groove in the top surface of the carrier supply layer may include forming a mask that covers a portion of the carrier supply layer; forming another carrier supply layer on the carrier supply layer in a region not covered by the mask; and removing the mask. The semiconductor layer may include nitrogen, and the channel layer may include nitrogen.

### BRIEF DESCRIPTION OF THE DRAWINGS

FIG. 1 shows an exemplary cross section of a semiconductor device 100 according to the present embodiment.

FIG. 2 is an exemplary cross-sectional view of a step for manufacturing the semiconductor device 100.

FIG. 3 is an exemplary cross-sectional view of a step for manufacturing the semiconductor device 100.

FIG. 4 is an exemplary cross-sectional view of a step for manufacturing the semiconductor device 100.

FIG. 5 is an exemplary cross-sectional view of a step for manufacturing the semiconductor device 100.

FIG. 6 is an exemplary cross-sectional view of a step for manufacturing the semiconductor device 100.

FIG. 7 is an exemplary cross-sectional view of a step for manufacturing the semiconductor device 100.

FIG. 8 is an exemplary cross-sectional view of a step for manufacturing the semiconductor device 100.

FIG. 9 is an exemplary cross-sectional view of a step for manufacturing the semiconductor device 100.

FIG. 10 is an exemplary cross-sectional view of a step for manufacturing the semiconductor device 100.

FIG. 11 is a graph showing transition characteristics of the drain current in a DC evaluation of the semiconductor device 100 obtained from the above embodiment and the semiconductor device 100 obtained from the comparative example.

### LIST OF REFERENCE NUMERALS

100 semiconductor device
102 wafer
104 buffer layer
106 channel layer
108 electron supply layer
110 groove
112 p-type semiconductor layer
114 insulating layer
116 control electrode
118 input/output electrode
120 passivation layer
122 element separation region
130 resist film
132 open portion
134 resist film
136 open portion
138 resist film
140 open portion
142 insulating film
144 metal film

### BEST MODE FOR CARRYING OUT THE INVENTION

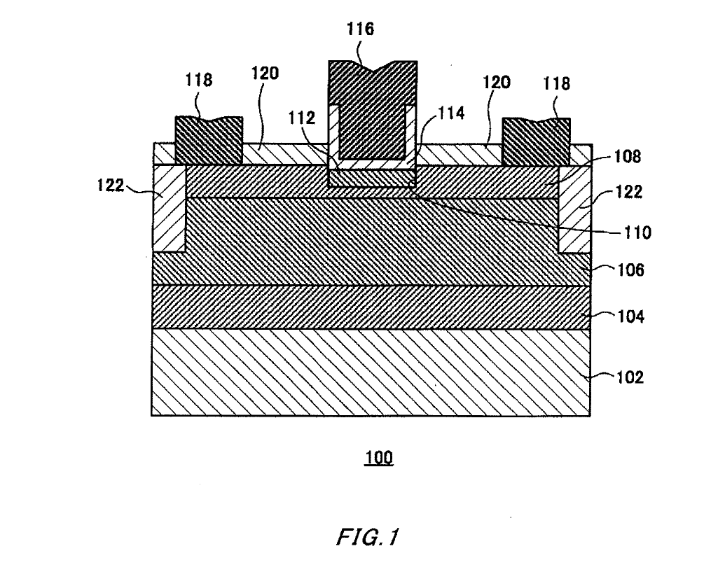

FIG. 1 shows an exemplary cross section of a semiconductor device 100 according to the present embodiment. The semiconductor device 100 of FIG. 1 is shown having a single transistor element, but the semiconductor device 100 may include many transistor elements. The semiconductor device 100 includes a wafer 102, a buffer layer 104, a channel layer 106, an electron supply layer 108, a groove 110, a p-type semiconductor layer 112, an insulating layer 114, a control electrode 116, input/output electrodes 118, a passivation layer 120, and an element separation region 122.

The wafer 102 may be a substrate wafer used for epitaxial growth, such as a single-crystal sapphire, silicon carbide, silicon, or gallium nitride. A commercially available wafer for epitaxial growth can be used for the wafer 102. The wafer 102 is preferably insulated, but n-types or p-types can also be used.

The buffer layer 104 is formed on the wafer 102, and can be formed of a group 3-5 compound semiconductor containing nitrogen. For example, the buffer layer 104 may be a single layer of aluminum gallium nitride (AlGaN), aluminum nitride (AlN), or gallium nitride (GaN), or may be obtained by layering a plurality of these layers. The film thickness of the buffer layer 104 is not particularly limited, but is preferably between 300 nm and 3000 nm. The buffer layer 104 can be formed using metalorganic vapor phase epitaxy (MOVPE), halide VPE, or molecular beam epitaxy (MBE). A commercially available organic metal raw material, such as trimethylgallium or trimethylindium, can be used as material for forming the buffer layer 104.

The channel layer 106 is formed on the buffer layer 104, and may be a group 3-5 compound semiconductor containing nitrogen. The channel layer 106 is preferably a GaN layer, but may instead be an InGaN layer or an AlGaN layer. The film thickness of the channel layer 106 is not particularly limited, but is preferably between 300 nm and 3000 nm. The channel layer 106 can be formed using the same methods used for forming the buffer layer 104, for example.

The electron supply layer 108 is an example of a carrier supply layer. The electron supply layer 108 supplies electrons to the channel layer 106. The electrons are an example of the carriers. The electron supply layer 108 is formed on the channel layer 106, and a 2DEG is formed on the channel layer 106 side of the interface between the channel layer 106 and the electron supply layer 108. The electron supply layer 108 may be formed to directly contact the channel layer 106, or may be formed with a suitable intermediate layer therebetween. The electron supply layer 108 may lattice match or pseudo-lattice match with the channel layer 106, and may be an AlGaN layer, an AlInN layer, or an AlN layer.

The film thickness of the electron supply layer 108 is determined to be within a range that is narrower than the critical film thickness estimated based on a difference in lattice constants between the channel layer 106 and the electron supply layer 108. This critical film thickness may be the film thickness for achieving mitigation of stress caused by defects in the crystal lattice resulting from stress caused by lattice mismatch. The critical film thickness depends on the Al composition and the In composition of each layer, but can be exemplified as being between 10 nm and 60 nm. The electron supply layer 108 can be formed using the same methods used for forming the buffer layer 104, for example.

The electron supply layer 108 has a groove 110 on a surface thereof that is opposite the surface facing the channel layer 106. Forming the groove 110 in the electron supply layer 108 enables the 2DEG in the lower portion of the groove 110 to be more easily depleted. As a result, the normally-off operation of the transistor can be more easily achieved.

The film thickness of the groove 110 can be determined according to threshold values for the transistor, film thickness, and composition of the p-type semiconductor layer 112. For example, the film thickness of the groove 110 can be between 5 nm and 40 nm. A preferable range of this film thickness is exemplified as being between 7 nm and 20 nm, a more preferable range is between 9 nm and 15 nm, and a most preferable range is between 10 nm and 13 nm.

The groove 110 can be formed by applying to the electron supply layer 108 a mask that includes an opening in a region where the groove 110 is formed, and performing anisotropic etching, such as dry etching, on the electron supply layer 108 exposed by the open portion of the mask. The mask may be any material that has etching selectivity relative to the electron supply layer 108, examples of which include photo resists, inorganic films such as SiOₓ, and metals. The etching gas can be a chloride-based gas such as Cl₂ or CH₂Cl₂ and a fluoride-based gas such as CHF₃ or CF₄.

Instead, the groove 110 can be formed by forming the mask in a region corresponding to the groove 110 after the electron supply layer 108 is formed, forming the electron supply layer 108 with the mask in place, and then removing the mask. This mask can be SiNₓ or SiOₓ, and in this case, the selective growth method can be used. This selective growth method may be MOVPE. By forming the electron supply layer 108 to have a suitable film thickness, the groove 110 need not be formed.

The p-type semiconductor layer 112 is an example of a semiconductor layer. The p-type semiconductor layer 112 has a groove 110 formed on a surface thereof that is opposite the surface facing the channel layer 106 of the electron supply layer 108. The p-type semiconductor layer 112 may lattice match or pseudo-lattice match with the electron supply layer 108. The p-type semiconductor layer 112 may be a p-type group 3-5 compound semiconductor containing nitrogen. For example, the p-type semiconductor layer 112 can be an InGaN layer, an AlGaN layer, or a GaN layer. In particular, the p-type semiconductor layer 112 may be an ALₓGa₁₋ₓN layer (0≦x≦0.5). The x composition can be selected as needed from a prescribed range, but since the AlGaN crystal has worse crystallinity when the Al composition is higher, a range of 0≦x≦0.4 is preferable, a range of 0≦x≦0.3 is more preferable, and a range of 0≦x≦0.2 is even more preferable.

By forming the p-type semiconductor layer 112 in the groove 110 of the electron supply layer 108, the channel potential is controlled via the p-type semiconductor layer 112, enabling modulation of the channel current. In other words, the potential of the p-type semiconductor layer 112 contacting the groove 110 can change in response to the potential of the control electrode 116, and the potential can change over the full range at the bottom surface of the groove 110 contacting the p-type semiconductor layer 112. As a result, the occurrence of parasitic resistance at the source end and drain end of the bottom surface of the groove (recess), such as seen in conventional transistors, can be prevented. Therefore, the semiconductor device 100 with a high current density can be manufactured.

Furthermore, since the p-type semiconductor layer 112 arranged on the bottom surface of the groove 110 is p-type, the channel potential can be increased more than in a case where an insulating film such as an oxide film with the same thickness is arranged on the electron supply layer 108. As a result, the threshold value of the semiconductor device 100 can be increased.

Doping with p-type impurities, such as Mg, can be used to achieve the p-type conduction. It is enough that the dopant concentration be sufficient to achieve p-type conduction. However, there is a concern that the crystallinity will worsen if the dosage has too high of a concentration, and so the dosage should be within a range from 1×10¹⁵ cm⁻² to 1×10¹⁹ cm⁻². The dosage of p-type impurities is preferably from 5×10¹⁵ cm⁻² to 5×10¹⁸ cm⁻², more preferably from 1×10¹⁶ cm⁻² to 1×10¹⁸ cm⁻², and even more preferably from 5×10¹⁶ cm⁻² to 5×10¹⁷ cm⁻².

Since the p-type semiconductor layer 112 is formed in the groove 110 of the electron supply layer 108, the normally-off operation is more easily achieved, and by forming the p-type semiconductor layer 112 in the groove 110, the film thickness of the electron supply layer 108 at the groove 110 can be increased. Even when the groove 110 is formed in the electron supply layer 108, a separation distance can be maintained between the channel and the bottom surface of the groove 110 located at an intermediate position, and so a transistor having a higher current density than conventional normally-off transistors can be obtained.

The film thickness of the p-type semiconductor layer 112 may be between 2 nm and 200 nm, preferably between 5 nm and 100 nm, and more preferably between 7 nm and 30 nm. The p-type semiconductor layer 112 can be formed using MOVPE, for example. When forming the p-type semiconductor layer 112 in the groove 110, the p-type semiconductor layer 112 can be selectively formed in the groove 110. For example, a selective growth method can be used that involves covering a region other than the groove 110 of the electron supply layer 108 with an inhibiting film that prevents epitaxial growth, using MOVPE, and then epitaxially growing an epitaxial film that becomes the p-type semiconductor layer 112 in a prescribed region where an opening is formed in the inhibiting film. The inhibiting film may be removed by etching, or may remain as the passivation layer 120. The inhibiting film can be a silicon nitride film or a silicon oxide film with a film thickness approximately between 10 nm and 100 nm, for example.

The insulating layer 114 can be formed on the p-type semiconductor layer 112. By forming the insulating layer 114, the leak current from the control electrode 116 to the channel can be decreased. The insulating layer 114 may be one or more of the insulating compounds selected from a group consisting of SiOₓ, SiNₓ, SiAlₓO_{y}N_{z}, HfOₓ, HfAlₓO_{y}, HfSiₓO_{y}, HfNₓO_{y}, AlOₓ, AlNₓO_{y}, GaOₓ, GaOₓN_{y}, TaOₓ, and TiNₓO_{y}. The chemical formulas including x, y, and z represent insulating compounds, as described above, and represent compounds whose elemental composition ratios are expressed as stoichiometric ratios or compounds whose elemental composition ratios are not expressed as stoichiometric ratios due to the inclusion of defects or amorphous structures. The insulating layer 114 can be formed using sputtering, CVD, or the like. The film thickness of the insulating layer 114 can be determined according to the dielectric constant and dielectric voltage thereof. The film thickness of the insulating layer 114 can be between 2 nm and 150 nm, preferably between 5 nm and 100 nm, more preferably between 7 nm and 50 nm, and most preferably between 9 nm and 20 nm.

The control electrode 116 may be formed to contact the p-type semiconductor layer 112. In other words, the insulating layer 114 need not be provided. Instead, the control electrode 116 may be formed on the insulating layer 114, which serves as an intermediate layer between the control electrode 116 and the p-type semiconductor layer 112. Instead of the insulating layer 114, the intermediate layer may be formed as an intrinsic (insulating) semiconductor layer.

The control electrode 116 can include at least one metal selected from the group containing Ni, Al, Mg, Sc, Ti, Mn, Ag, Sn, Pt, and In, and among these, Al, Mg, Sc, Ti, Mn, Ag, and In are preferable. Furthermore, Al, Ti, and Mg are more preferable. The control electrode 116 can be formed using vapor deposition.

The input/output electrodes 118 are formed on the electron supply layer 108. The input/output electrodes 118 are formed by vapor deposition of metals such as Ti and Al, for example, are then machined to have a prescribed shape using a lift-off process, and are annealed at a temperature between 700° C. and 800° C.

The passivation layer 120 covers the electron supply layer 108 in a region other than the region where the control electrode 116 and the input/output electrodes 118 are formed. The passivation layer 120 can function as a mask for the selective growth as described below, and in this case, the passivation layer 120 includes an open portion that matches the opening of the groove 110. The passivation layer 120 can be a silicon nitride film or a silicon oxide film with a film thickness between approximately 10 nm and 100 nm, for example.

The element separation region 122 is formed with the electron supply layer 108 passing therethrough, in a manner to surround the active region of the transistor. The element separation region 122 defines a region in which current flows. The element separation region 122 can be formed by forming a separating groove by etching and then implanting an insulator such as a nitride, for example. Instead, the element separation region 122 can be formed by ion implantation in the formation region using nitrogen or hydrogen.

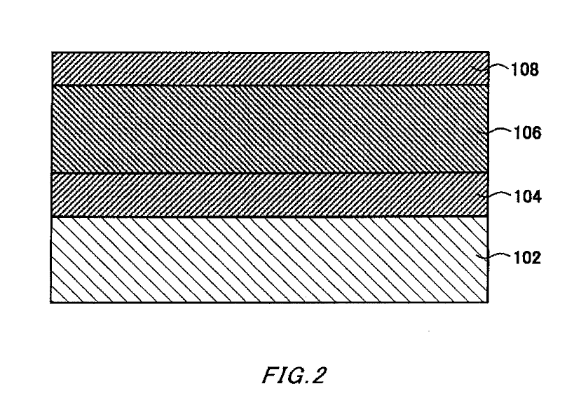

FIGS. 2 to 10 are exemplary cross sections showing a process for manufacturing the semiconductor device 100. As shown in FIG. 2, the wafer 102 is prepared having the channel layer 106 that is a group 3-5 compound semiconductor containing nitrogen and the electron supply layer 108 that supplies electrons to the channel layer 106, and the electron supply layer 108 serves as the top surface. The wafer 102 may include the buffer layer 104, and the wafer formed by sequentially layering the buffer layer 104, the channel layer 106, and the electron supply layer 108 and having the electron supply layer 108 as the top surface may be provided as an epitaxial wafer for forming an HEMT.

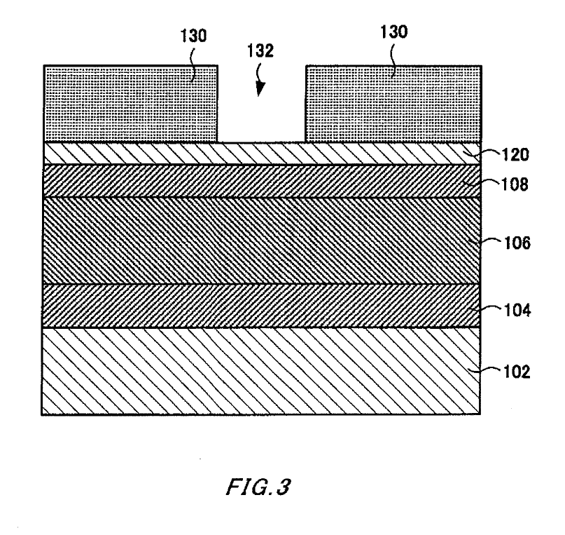

As shown in FIG. 3, the passivation layer 120 is formed to cover the electron supply layer 108, and then the resist film 130 is formed on the passivation layer 120. An open portion 132 is formed in the resist film 130 by spin coating a suitable resist material on the wafer, pre-baking the resist material, exposing the resist material, post-baking the resist material, and finally removing the exposed region. The open portion 132 is formed in the region where the groove 110 is to be formed.

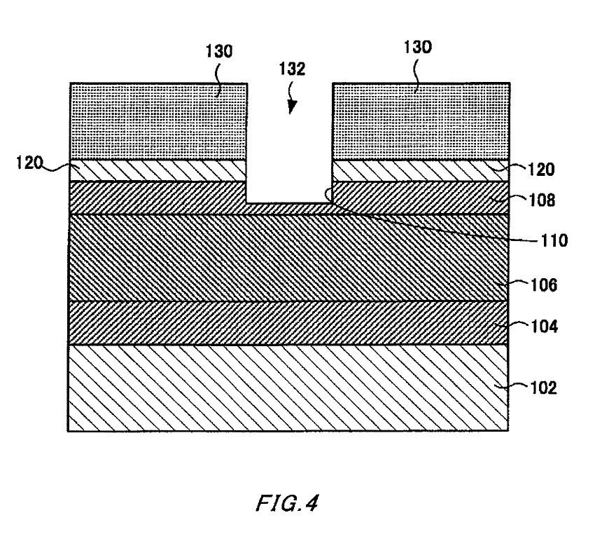

As shown in FIG. 4, an open portion is formed in the passivation layer 120 at the region where the groove 110 is to be formed, i.e. at the open portion 132. The groove 110 is then formed by etching the electron supply layer 108 exposed in the open portion of the passivation layer 120. Specifically, the groove 110 can be formed by a first etching step that involves etching the passivation layer 120 with the resist film 130 as a mask and a second etching step that involves etching the electron supply layer 108 with the resist film 130 as a mask. In the second etching step, the resist film 130 can be removed and the passivation layer 120 can be used as a mask for the etching. Furthermore, the groove 110 can be formed by, after the electron supply layer having a film thickness corresponding to the bottom surface of the groove 110 is formed and a portion of the electron supply layer 108 is covered by a mask, forming the electron supply layer 108 again in a region corresponding to the portion of the electron supply layer 108 that is not covered by the mask and then removing the mask.

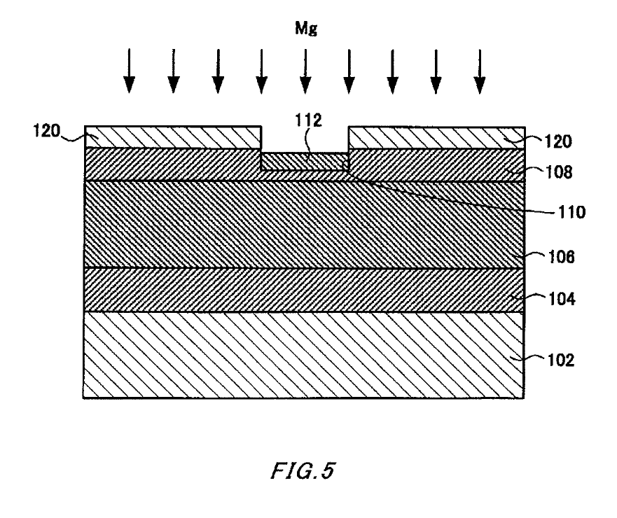

As shown in FIG. 5, the p-type semiconductor layer 112 that is a group 3-5 compound semiconductor containing nitrogen is formed on the top surface of the electron supply layer 108. The p-type semiconductor layer 112 may be formed in the groove 110 of the electron supply layer 108. An epitaxial layer that becomes the p-type semiconductor layer 112 may be selectively grown in on the electron supply layer 108 in the region exposed by the open portion of the passivation layer 120. After this, the semiconductor layer is doped with p-type impurities such as Mg using ion implantation, for example.

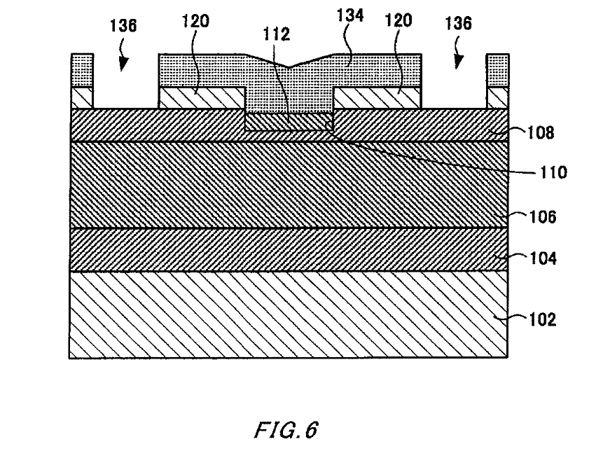

As shown in FIG. 6, the resist film 134 is formed to cover the passivation layer 120 and the p-type semiconductor layer 112 in the groove 110. An open portion 136 is formed in the resist film 134 by spin coating a suitable resist material on the wafer, pre-baking the resist material, exposing the resist material, post-baking the resist material, and finally removing the exposed region. The open portions 136 are formed in the regions where the input/output electrodes 118 are to be formed. After this, the passivation layer 120 is etched with the resist film 134 as a mask.

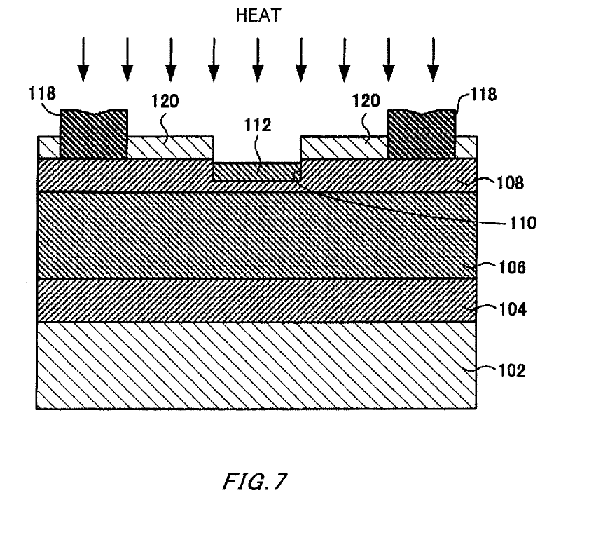

As shown in FIG. 7, after a metal film that becomes the input/output electrodes 118 is formed using vapor deposition or the like, the input/output electrodes 118 are formed by a lift-off process that removes the resist film 134 and leaves behind the metal film in the open portions 136. After forming the input/output electrodes 118, annealing may be performed by increasing the temperature. The metal film may be a layered metal film.

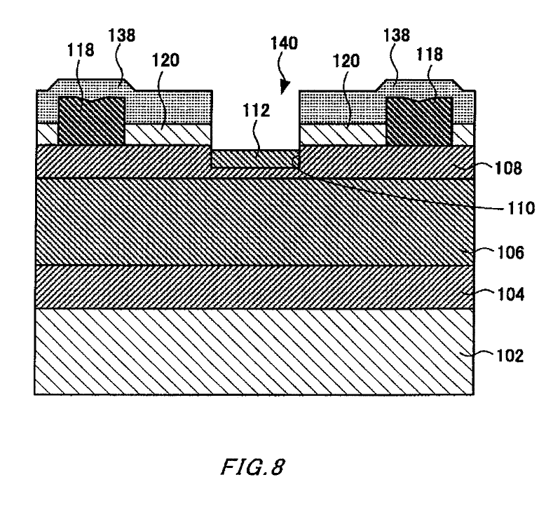

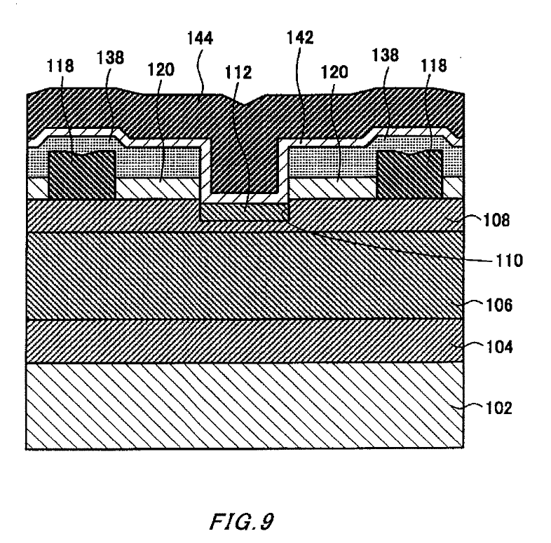

As shown in FIG. 8, the resist film 138 is formed and the open portion 140 that exposes the p-type semiconductor layer 112 in the groove 110 is formed in the resist film 138. Then, as shown in FIG. 9, the insulating film 142 and the metal film 144 that respectively become the insulating layer 114 and the control electrode 116 are formed. The insulating film 142 and the metal film 144 may respectively be a layered insulating film and a layered metal film.

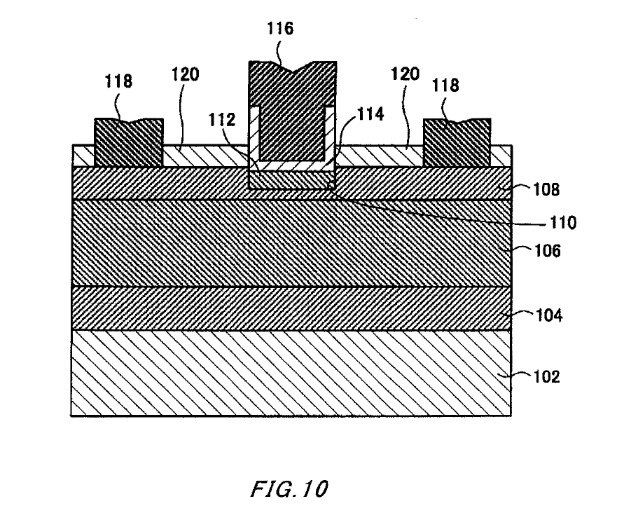

As shown in FIG. 10, the insulating layer 114 and the control electrode 116 are formed by a lift-off process that removes the resist film 138 and leaves behind the insulating film 142 and the metal film 144 in the open portion 140. In other words, the control electrode 116 is formed after forming the p-type semiconductor layer 112.

Next, a suitable mask having an opening in a region that becomes the element separation region 122 is formed, and the element separation region 122 is formed by performing selective ion implantation in the open portion of the mask. The ions implanted in the element separation region 122 may be nitrogen or hydrogen, for example, and can be any type of ion that causes the electron supply layer 108 and the channel layer 106 to serve as insulators. The semiconductor device 100 shown in FIG. 1 can be manufactured in the manner described above.

In the semiconductor device 100 and manufacturing method thereof according to the present embodiment, since the p-type semiconductor layer 112 is formed under the control electrode 116, the channel current density can be increased while the semiconductor device 100 operates in the normally-off mode, and the threshold value can be increased. Furthermore, since the p-type semiconductor layer 112 is formed in the groove 110, the effect of the groove 110 is multiplied, enabling even easier normally-off operation and a greater increase in the channel current density.

### EMBODIMENT

A sapphire was prepared as the wafer 102. An epitaxial wafer to be used as an HEMT was formed by using MOVPE to sequentially layer on the wafer 102 a GaN layer as the buffer layer 104, a GaN layer as the channel layer 106, and an AlGaN layer as the electron supply layer 108. The film thickness for these three layers was respectively 100 nm, 2000 nm, and 30 nm. The Al composition of the AlGaN electron supply layer 108 was 25%.

Sputtering was used to form an SiNₓ layer with a film thickness of 100 nm as the passivation layer 120 on the AlGaN electron supply layer 108. The resist film 130 was formed on the SiNₓ passivation layer 120, and lithography was used to form the open portion 132 in the resist film 130 at a position where the groove 110 was to be formed. The dimensions of the open portion 132 were 30 μm by 2 μm.

ICP plasma etching with CHF₃ gas was used to remove the SiNₓ passivation layer 120 exposed by the open portion 132 of the resist film 130. In this way, the SiNₓ passivation layer 120 having an open portion was formed. Next, the etching gas was changed to CHCl₂, and the AlGaN electron supply layer 108 was etched to a depth of 20 nm. As a result, the groove 110 was formed in the electron supply layer 108.

The resist film 130 on the top surface was removed by acetone, and the wafer 102 was then moved to an MOVPE reactor in which epitaxial growth was performed until a GaN film with a film thickness of 20 nm was selectively grown in the groove 110. The GaN film was then doped with Mg to form the p-type semiconductor layer 112. The hole concentration of the p-type semiconductor layer 112 after doping was 5×10¹⁷ cm⁻²

After removing the wafer 102 from the reactor, the resist film 134 was formed and lithography was used to form the open portions 136 in the resist film 134 to have the shape of the input/output electrodes 118. Using the same method described above, the SiNₓ passivation layer 120 exposed by the open portions 136 was removed. Vapor deposition was then used to form a Ti/Al/Ni/Au layered film, and a lift-off process was used to create the shape of the input/output electrodes 118. Next, the wafer 102 was annealed in a nitrogen atmosphere at 800° C. for 30 seconds. In this way, a pair of input/output electrodes 118 was formed.

The resist film 138 was formed and lithography was used to form the open portion 140 in the resist film 138 on the GaN p-type semiconductor layer 112. The width of the open portion 140 was 1.5 μm. Vapor deposition was used to form the SiOₓ insulating film 142 with a film thickness of 10 nm and an Ni/Au layered metal film serving as the metal film 144, and a lift-off process was used to form Ni/Au control electrodes 116 and the insulating layer 114. Furthermore, nitrogen was ion-implanted around the periphery of these elements with the resist film as a mask to form the element separation region 122. In this way, the semiconductor device 100 shown in FIG. 1 was manufactured.

### COMPARATIVE EXAMPLE

In the same way as in the above embodiment, an epitaxial wafer to be used as an HEMT was formed by layering on a sapphire wafer 102 a GaN buffer layer 104, a GaN channel layer 106, and an AlGaN electron supply layer 108. In the same way as in the above embodiment, the SiNₓ passivation layer 120, the groove 110, and the pair of input/output electrodes 118 were formed. Without forming the p-type semiconductor layer 112 in the groove 110, the same techniques as in the above embodiment were used to form the metal film 144 that becomes the control electrode 116 and the insulating film 142 that becomes the SiOₓ insulating layer 114 directly on the bottom surface of the groove 110, and the insulating layer 114 and control electrode 116 were then formed. The element separation region 122 was then formed using the same techniques as in the above embodiment.

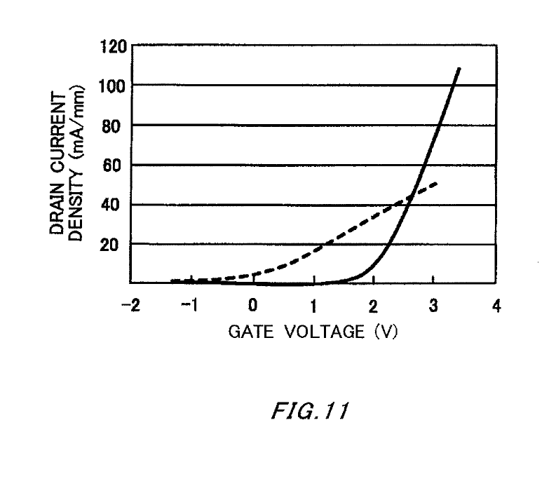

FIG. 11 is a graph showing transition characteristics of the drain current in a DC evaluation of the semiconductor device 100 obtained from the above embodiment and the semiconductor device 100 obtained from the comparative example. The solid line represents the above embodiment and the dashed line represents the comparative example. The horizontal axis represents the drain voltage, and the vertical axis represents the drain current. The maximum current density of the comparative example is approximately 50 mA/mm near a gate voltage of 3 V, while the maximum current density of the above embodiment is higher, being 110 mA/mm near a gate voltage of 3.5 V. As shown by the results of the comparison between the above embodiment and the comparative example, including the p-type semiconductor layer 112 achieves an increase in the channel current density while allowing the semiconductor device 100 to operate in the normally-off mode.

1. A semiconductor device comprising:
a group 3-5 compound semiconductor channel layer;
a carrier supply layer that has a groove in a surface thereof that is opposite a surface facing the channel layer and that supplies the channel layer with carriers;
a semiconductor layer that is formed in the groove of the carrier supply layer and that has a conduction type opposite that of the carriers; and
a control electrode disposed on the semiconductor layer.

2. The semiconductor device according to claim 1, wherein the semiconductor layer is a group 3-5 compound semiconductor layer including nitrogen.

3. The semiconductor device according to claim 2, wherein the semiconductor layer is an InGaN layer, an AlGaN layer, or a GaN layer.

4. The semiconductor device according to claim 3, wherein the semiconductor layer is an AlₓGa₁₋ₓN layer, where 0≦x≦0.5.

5. The semiconductor device according to claim 1, wherein
an insulating layer is formed between the control electrode and the semiconductor layer.

6. The semiconductor device according to claim 5, wherein the insulating layer is a layer including at least one insulating compound selected from a group consisting of SiOₓ, SiNₓ, SiAlₓO_{y}N_{z}, HfOₓ, HfAlₓO_{y}, HfSiₓO, HfNₓO_{y}, AlOₓ, AlNₓO_{y}, GaOₓ, GaOₓN_{y}, TaOₓ, and TiNₓO_{y}.

7. The semiconductor device according to claim 1, further comprising a passivation layer that covers the carrier supply layer and that includes an open portion matching an opening of the groove.

8. The semiconductor device according to claim 1, wherein
the carrier supply layer lattice matches or pseudo-lattice matches with the channel layer, and
the semiconductor layer lattice matches or pseudo-lattice matches with the carrier supply layer.

9. The semiconductor device according to claim 1, wherein the channel layer includes nitrogen.

10. The semiconductor device according to claim 9, wherein the channel layer is a GaN layer, an InGaN layer, or an AlGaN layer, and the carrier supply layer is an AlGaN layer, an AlInN layer, or an AlN layer.

11. The semiconductor device according to claim 1, wherein
the control electrode includes at least one metal selected from a group consisting of Ni, Al, Mg, Sc, Ti, Mn, Ag, Sn, Pt, and In.

12. The semiconductor device according to claim 1, wherein the carriers are electrons.

13. A method of manufacturing a semiconductor device, comprising:
forming a groove in a top surface of a carrier supply layer that supplies a group 3-5 compound semiconductor channel layer with carriers;
forming, in the groove of the carrier supply layer, a semiconductor layer that has a conduction type opposite that of the carriers; and
after forming the semiconductor layer, forming a control electrode.

14. The method of manufacturing a semiconductor device according to claim 13, further comprising:
forming a passivation layer that covers the carrier supply layer; and
forming an open portion in the passivation layer in a region where the groove is formed, wherein
forming the groove in the top surface of the carrier supply layer includes forming the groove by etching the carrier supply layer that is exposed by the open portion of the passivation layer.

15. The method of manufacturing a semiconductor device according to claim 14, wherein
forming the semiconductor layer includes selectively growing an epitaxial layer that becomes the semiconductor layer on the carrier supply layer exposed by the open portion of the passivation layer.

16. The method of manufacturing a semiconductor device according to claim 13, wherein forming the groove in the top surface of the carrier supply layer includes:
forming a mask that covers a portion of the carrier supply layer;
forming another carrier supply layer on the carrier supply layer in a region not covered by the mask; and
removing the mask.

17. The method of manufacturing a semiconductor device according to claim 13, wherein
the semiconductor layer includes nitrogen, and
the channel layer includes nitrogen.
